(19) United States
(12) Patent Application Publication
(10) Pub. No.: US 2024/0351311 A1
(43) Pub. Date: Oct. 24, 2024

(54) Multi-Layer Glass for Foldable Devices

(71) Applicant: Apple Inc., Cupertino, CA (US)

(72) Inventors: Christopher D Jones, Los Gatos, CA (US); Que Anh S Nguyen, San Jose, CA (US); Matthew S Rogers, San Jose, CA (US); Christopher C Bartlow, Menlo Park, CA (US)

(21) Appl. No.: 18/596,022

(22) Filed: Mar. 5, 2024

Related U.S. Application Data
(60) Provisional application No. 63/497,976, filed on Apr. 24, 2023.

(51) Int. Cl. B32B 17/06; B32B 3/30; B32B 7/027; H05K 5/03

(52) U.S. Cl. CPC B32B 17/06; B32B 3/30; B32B 7/027; H05K 5/03; B32B 2250/03; B32B 2307/30; B32B 2307/7376; B32B 2457/20

(57) ABSTRACT

An electronic device may have a display and may be configured to fold about a bend axis that overlaps the display. The display may have a display cover layer formed from three layers of glass fused together. The display cover layer may have outer glass layers that have lower coefficients of thermal expansion than a core inner layer that is formed between the outer glass layers. This places the outer glass layers into deep compressive stress relative to the inner layer, which is under tensile stress. A notch may be formed in one of the outer glass layers to enhance flexibility of the display cover layer in a strip-shaped notch region that extends along the bend axis. An exposed portion of the inner glass layer in the notch may be chemically strengthened.

This application claims the benefit of provisional patent application No. 63/497,976, filed Apr. 24, 2023, which is hereby incorporated by reference herein in its entirety.

### FIELD

This relates generally to electronic devices, and, more particularly, to glass for foldable electronic devices.

### BACKGROUND

Electronic devices may have displays. An electronic device display may be used to present information for a user. In some devices, displays may be covered with protective cover glass.

### SUMMARY

An electronic device may have a display and may be configured to fold about a bend axis that overlaps the display. The display may have a display cover layer formed from three layers of glass fused together. The display cover layer may have a flexible portion that overlaps the bend axis and allows the display cover layer to bend.

The layers of glass material in the display cover layer may have different compositions with different properties. In an illustrative configuration, a core inner layer is sandwiched between a pair of outer glass layers that have lower coefficients of thermal expansion than the core inner layer. As the laminated glass layers cool during fabrication, this arrangement places the outer glass layers into compressive stress relative to the inner layer, which is under tensile stress. The outer glass layers may be relatively thick, so that the compressive stress penetrates deeply into the display cover layer to provide protection from damage due to exposure from sharp objects.

A notch may be formed in an inwardly facing one of the outer glass layers to enhance flexibility of the display cover layer in a strip-shaped flexible portion that extends along the bend axis. An exposed portion of the inner glass layer in the notch may be chemically strengthened so that this portion of the inner glass layer is placed under compressive stress rather than tensile stress. This helps prevent cracking in the notch when the display cover layer is folded.

### BRIEF DESCRIPTION OF THE DRAWINGS

FIG. 1 is a side view of an illustrative electronic device with a display in a partly folded configuration in accordance with an embodiment.

FIG. 2 is a top view an illustrative display cover layer in an unfolded configuration in accordance with an embodiment.

FIG. 3 is a cross-sectional side view of an illustrative display cover layer in accordance with an embodiment.

### DETAILED DESCRIPTION

Electronic devices may be provided with displays. Displays may be used for displaying images for users. Displays may be formed from arrays of light-emitting diode pixels or other pixels. For example, a device may have a flexible organic light-emitting diode display or a flexible display formed from an array of micro-light-emitting diodes (e.g., diodes formed from crystalline semiconductor dies). Electronic devices with flexible displays may be provided with hinges so that the devices can be folded for storage.

FIG. 1 is a side view of an illustrative folding electronic device in a partly folded configuration. Device 10 of FIG. 1 may be a portable device such as a cellular telephone, tablet computer, or laptop computer, or may be any other suitable electronic device with a display.

Device 10 may include control circuitry. The control circuitry may include storage and processing circuitry for supporting the operation of device 10. The storage and processing circuitry may include storage such as nonvolatile memory (e.g., flash memory or other electrically-programmable-read-only memory configured to form a solid state drive), volatile memory (e.g., static or dynamic random-access-memory), etc. Processing circuitry in the control circuitry may be used to gather input from sensors and other input devices and may be used to control output devices. The processing circuitry may be based on one or more microprocessors, microcontrollers, digital signal processors, baseband processors and other wireless communications circuits, power management units, audio chips, application specific integrated circuits, etc. During operation, the control circuitry of device 10 may use a display such as display 14 and other output devices in providing a user with visual output and other output.

Display 14 may have an array of pixels such as pixel array 22 (sometimes referred to as a display or display layer) that is configured to display images for a user. The pixels may be formed as part of a display panel that is bendable. This allows device 10 to be folded and unfolded about a bend axis. For example, a flexible (bendable) display in device 10 may be folded so that device 10 may be placed in a compact shape for storage and may be unfolded when it is desired to view images on the display. Pixel array (display) 22 may be covered by a transparent protective layer such as display cover layer 20. Display cover layer 20 may be formed from glass, glass-ceramic, transparent ceramic, transparent crystalline materials such as sapphire, or other transparent protective material.

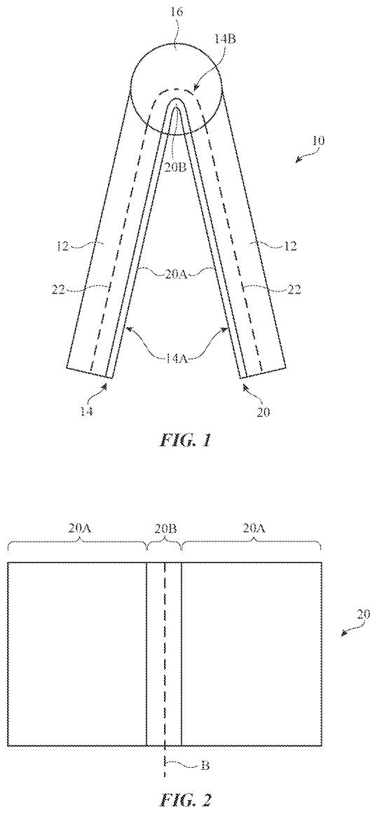

As shown in FIG. 1, device 10 may have a housing such as housing 12 in which display 14 is mounted. Hinge 16 may be used to attach first and second portions of housing 12 together. Hinge 16 allows the first and second portions (left and right sides) of housing 12 to rotate with respect to each other about a hinge axis (sometimes referred to as a fold axis or bend axis). Display 14 may have planar portions such as portions 14A and a bendable portion such as bendable portion 14B that is located between the planar portions. When device 10 is in an unfolded (planar) configuration, portion 14B is unbent (planar). When the left and right sides of device 10 are folded together as shown in FIG. 1, portion 14B bends. To prevent display cover layer 20 from becoming damaged (e.g., cracking) when device 10 is folded, display cover layer 20 may have a strip-shaped bendable portion such as portion 20B that overlaps hinge 16 and extends along its associated bend axis (see, e.g., bend axis B of FIG. 2, which shows a top view of layer 20). The width of portion 20B orthogonal to bend axis B may be 20 mm, 10-30 mm, 1-50 mm, at least 0.5 mm, less than 60 mm, or other suitable width.

Because portion 20B of layer 20 must bend during folding and unfolding operations, it is desirable for portion 20B to be highly flexible and to exhibit high compressive surface stress. This helps enhance the bendability and bending strength of portion 20B. Planar portions 20A of display cover layer 20 may be supported by planar portions of housing 12 and need not be as flexible as bendable portion 20B. Accordingly, it may be desirable to provide portions 20A with deep compressive stress so that portions 20A are highly resistant to puncture and other damage from contact with sharp objects.

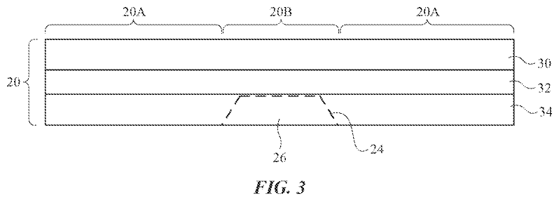

In an illustrative embodiment, these requirements may be satisfied using a laminated arrangement for display cover layer 20. A cross-sectional side view of display cover layer 20 in an illustrative arrangement in which layer 20 has multiple laminated sublayers of different materials is shown in FIG. 3. As shown in FIG. 3, layer 20 may have a first layer such as layer 30 (e.g., a layer that faces outwardly from device 10 and that faces away from pixel array 22 of FIG. 1), a second layer such as layer 32, and a third layer such as layer 34 (which may face pixel array 22 of FIG. 1). Some or all of layer 34 may be removed in a strip that runs under strip-shaped portion 20B and extends along bend axis B (FIG. 2), as shown by notch (removed area) 24 of FIG. 3. This recess in layer 20 may be filled with index-matched polymer 26 or other clear flexible material, so that images on pixel array 22 are not optically distorted when a viewer views pixel array 22 through layer 20.

Outer layers 30 and 34 of layer 20 may have a thickness of 40 microns, at least 20 microns, at least 30 microns, less than 80 microns, less than 70 microns, 20-80 microns, or other suitable thickness. Inner layer 32 may have a thickness of 120 microns, 10-240 microns, or other suitable thickness. The total thickness of layer 20 (the combined thickness of layers 30, 32, and 34 in portions 20A, away from notch 24) may be 50-350 microns, 100-300 microns, 150-250 microns, at least 75 microns, at least 100 microns, at least 150 microns, at least 160 microns, at least 200 microns, less than 300 microns, or other suitable thickness. Layers 30, 32, and/or 34 may be formed from transparent materials such as glass, glass-ceramic, transparent ceramic, or crystalline material. In an illustrative configuration, which may sometimes be described as an example, layers 30, 32, and 34 may be formed from glass.

Outer layers 30 and 34 may be formed from the same type of glass or may be formed from different types of glass. In an illustrative embodiment, outer layers 30 and 34 are formed from the same type of glass. To provide deep compressive stress to the outer surfaces of layer 20, outer layers 30 and 34 may be formed from a first type of glass that has a first coefficient of thermal expansion (or two different materials with different respective coefficients of expansion), whereas layer 32 may be formed from a second type of glass that has a second coefficient of thermal expansion that is greater than the first coefficient of expansion (or that is greater than the coefficients of thermal expansion of each of layers 30 and 34 in arrangements in which layers 30 and 34 are formed from different materials). As an example, the second coefficient of thermal expansion may be at least 10%, at least 30%, or at least 50% greater than the coefficient of thermal expansion of layer 30 and/or may be at least 10%, at least 30%, or at least 50% greater than the coefficient of thermal expansion of layer 32.

During fabrication of layer 20, layers 30, 32, and 34 may be laminated together in a stack by heating and fusing layers 30, 32, and 34 together at elevated temperatures or otherwise fabricating a single glass layer by joining layers 30, 32, and 34 directly to each other (without intervening adhesive) at an elevated temperature. As layers 30, 32, and 34 cool, the higher coefficient of thermal expansion of layer 32 relative to layers 30 and 34 causes layer 32 to contract more than layers 30 and 34. This places layers 30 and 34 under compressive stress (e.g., 250-900 MPa of stress or other suitable amount of compressive stress) and places layer 32 under tensile stress. Due to the relatively large thicknesses of layers 30 and 34, the compressive stress profile of layer 20 penetrates relatively deeply into layer 20 (e.g., tens of microns), which helps ensure that layer 20 (e.g., portions 20A) will be satisfactorily resistant to sharp damage. As an example, the compressive stress on each of the outer surfaces of layer 20 may penetrate at least 15%, at least 20%, at least 25%, at least 30%, or at least 35% into the total thickness of layer 20. If, as an example, the total thickness of layer 20 is 200 microns, layer 20 may be compressively stressed at least 40 microns, at least 50 microns, or at least 66 microns into layer 20 from each of the surfaces of layer 20, whereas the remaining core portion of layer 20 may be under tensile stress. By ensuring that the depth of the compressively stressed portion of layer 20 is sufficiently large (e.g., at least 20%, at least 25%, at least 30%, or at least 35% of the total thickness of layer 20), layer 20 (e.g., portions 20A) may be satisfactorily resistant to damage when exposed to sharp objects during use of device 10.

If desired, the flexibility of strip-shaped portion 20B of layer 20 may be enhanced by removing some or all of layer 34 in portion 20B (see, e.g., notch 24 in layer 34 of FIG. 3) and notch 24 may be filled with flexible index-matched polymer 26. In this type of arrangement, the total thickness remaining in glass layer 20 (e.g., the combined thickness of layers 30 and 32 in the portion of layer 20 that overlaps the bend axis and notch 24) may be 30-150 microns, 50-125 microns 75-90 microns, at least 60 microns, less than 50 microns, less than 95 microns, less than 100 microns, less than 125 microns, less than 150 microns, or other suitable thickness that is sufficiently small to allow portion 20B to bend as device 10 is folded and unfolded. Notch 24 may be formed only in layer 34 (without penetrating into layer 32) or may, if desired, penetrate partway into layer 32. Chemical etching or other notch formatting techniques may be used to form notch 24.

To ensure sufficient compressive surface stress in the exposed surface of layer 32 in notch 24 of portion 20B, layer 20 may be chemically strengthened following formation of notch 24. For example, the exposed surface of layer 32 may be placed in compressive stress using an ion-exchange process. During the ion-exchange process, smaller ions in the glass may be replaced with larger ions. For example, sodium in the glass at the exposed surfaces of layer 32 may be replaced by potassium. This creates compressive stress within the treated surface layers of layer 32 in notch 24 and prevents tensioned portions of layer 20 from being exposed at the surface of layer 20. The presence of chemically strengthened glass at the surface of layer 32 in notch 24 thereby helps to ensure that portion 20B can bend satisfactorily without experiencing cracking or other damage (e.g., when glass layer 20 is bent to form a bend radius of 4-6 mm (as an example). During chemical strengthening, layer 20 may be immersed in an ion-exchange bath for a relatively short amount of time so as to avoid excessively exposing layers 30 and 34 to elevated temperatures that could cause the compressive stress in layers 30 and 34 to relax. The depth of the chemically strengthened layer at the surface of layer 32 in notch 24 may be relatively shallow (e.g., 5-15 microns), because this exposed surface of layer 32 faces the interior of device 10 when device 10 is folded and will therefore not be exposed to scratching or other damage due to exposure to sharp objects.

To help protect the privacy of users, any personal user information that is gathered by electronic devices may be handled using best practices. These best practices including meeting or exceeding any privacy regulations that are applicable. Opt-in and opt-out options and/or other options may be provided that allow users to control usage of their personal data.

The foregoing is merely illustrative and various modifications can be made to the described embodiments. The foregoing embodiments may be implemented individually or in any combination.

What is claimed is:

1. A display cover layer configured to bend about a bend axis, comprising:
a first glass layer;
a second glass layer; and
a third glass layer, wherein the second glass layer is fused between the first and third glass layers.

2. The display cover layer defined in claim 1 wherein the first glass layer has a first coefficient of thermal expansion, wherein the second glass layer has a second coefficient of thermal expansion, wherein the third glass layer has the first coefficient of thermal expansion, and wherein the second coefficient of thermal expansion is greater than the first coefficient of thermal expansion.

3. The display cover layer defined in claim 2 further comprising a strip-shaped notch in the third glass layer that extends along the bend axis.

4. The display cover layer defined in claim 3 wherein the strip-shaped notch in the third glass layer passes through the third glass layer and exposes a portion of the second glass layer in the strip-shaped notch.

5. The display cover layer defined in claim 4 wherein the exposed portion of the second glass layer in the strip-shaped notch comprises chemically strengthened glass.

6. The display cover layer defined in claim 5 wherein the first, second, and third glass layers are characterized by a combined thickness of at least 160 microns away from the strip-shaped notch.

7. The display cover layer defined in claim 6 wherein the first and second layers have a combined thickness of less than 150 microns away from the strip-shaped notch.

8. The display cover layer defined in claim 7 wherein the strip-shaped notch has a width of 1-50 mm.

9. The display cover layer defined in claim 8 wherein the second coefficient of thermal expansion is at least 10% greater than the first coefficient of thermal expansion.

10. The display cover layer defined in claim 9 wherein first, second, and third layers are fused to form a glass layer with a total thickness and first and second opposing surfaces, and wherein the glass layer is characterized by a core portion with tensile stress and first and second compressively stressed surface portions that penetrate to first and second depths of at least 20% of the total thickness into the glass layer from the first and second surfaces, respectively.

11. A foldable device configured to fold about a bend axis, comprising:
a display that overlaps the bend axis; and
a glass display cover layer that overlaps the bend axis and that is configured to bend about the bend axis, wherein the glass display cover layer comprises first, second, and third glass layers that are fused together with the second glass layer between the first and third glass layers, wherein the second glass layer has a larger coefficient of thermal expansion than the first and third glass layers, and wherein the first and third glass layers have compressively stressed surface portions.

12. The foldable device defined in claim 11 wherein the glass display cover layer has a total thickness and wherein the compressively stressed surface portions of the first and third glass layers each penetrate at least 25% of the total thickness into the glass display cover layer.

13. The foldable device defined in claim 12 wherein the glass display cover layer has a notch that extends along the bend axis.

14. The foldable device defined in claim 13 further comprising:
chemically strengthened glass on an exposed portion of the display cover layer in the notch; and
polymer in the notch.

15. The foldable device defined in claim 14 wherein the glass display cover layer has a first portion that overlaps the notch and has a thickness of less than 125 microns and has a second portion that does not overlap that notch and has a thickness of at least 150 microns.

16. The foldable device defined in claim 14 wherein the glass display cover layer has a first portion that overlaps the notch and has a thickness of less than 50 microns and has a second portion that does not overlap that notch and has a thickness of at least 100 microns.

17. A display cover layer for a foldable electronic device that is configured to bend about a bend axis, the display cover layer comprising:
first, second, and third layers of glass that are fused together to form a glass cover layer, wherein the first and third layers of glass have coefficients of thermal expansion that are lower than the second layer of glass, wherein the second layer of glass is between the first and third layers of glass, and wherein the third layer of glass has a notch that overlaps the bend axis.

18. The display cover layer defined in claim 17 wherein the first and third layers of glass are under compressive stress and the second layer is under tensile stress.

19. The display cover layer defined in claim 18 wherein the first and third layers of glass are at least 20 microns thick.

20. The display cover layer defined in claim 18 wherein the notch passes through the third layer and exposes a surface portion of the second layer of glass that extends along the bend axis and wherein the surface portion of the second layer of glass comprises chemically strengthened glass.
